(19) United States
(12) Patent Application Publication
(10) Pub. No.: US 2026/0293270 A1
(43) Pub. Date: Sep. 24, 2026

(54) ELECTRONIC CIRCUIT WITH SELECTOR GATE HAVING A NTRIDE-BASED DIELECTRIC BARRIER AND METHODS OF MANUFACTURING THEREOF

(71) Applicant: Micron Technology, Inc., Boise, ID (US)

(72) Inventors: Ramanathan Gandhi, Singapore (SG); Juan Li, Singapore (SG); Dmitry Mikulik, Meridian, ID (US)

(21) Appl. No.: 19/085,493

(22) Filed: Mar. 20, 2025

(51) Int. Cl. H10D 64/68; H10B 41/20; H10B 41/41; H10B 43/20; H10B 43/40; H10D 64/01; H10D 64/66

(52) U.S. Cl. CPC H10D 64/693; H10B 41/20; H10B 41/41; H10B 43/20; H10B 43/40; H10D 64/037; H10D 64/662; H10D 64/667; H10D 64/691

(57) ABSTRACT

A method includes forming a tier stack of an electronic circuit, the tier stack including a plurality of tiers. A tier includes a first layer of first dielectric material and a second layer of second dielectric material. The method further includes forming a selector gate within the tier stack at the second layer of at least one of the plurality of tiers. The selector gate includes a nitride-based dielectric barrier adjacent to a metalloid layer. The metalloid layer includes a first metalloid. The method further includes selectively etching the second layer of second dielectric material of each of the plurality of tiers to form a void within each of the plurality of tiers. The method further includes filling the void within each of the plurality of tiers with a conductive material to form a plurality of conductive lines.

### TECHNICAL FIELD

Embodiments of the disclosure relate generally to memory sub-systems, and more specifically, relate to an electronic circuit with a selector gate having a nitride-based dielectric barrier and methods of manufacturing thereof.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-G are cutaway schematic representations illustrating a method of manufacturing an electronic circuit with a selector gate having a nitride-based dielectric barrier, in accordance with some embodiments of the present disclosure.

FIGS. 2A-D are cutaway schematic representations of portions of nitride-based dielectric barriers, in accordance with some embodiments of the present disclosure.

FIG. 3 is a flow diagram of an example method of manufacturing an electronic circuit having a nitride-based dielectric barrier, in accordance with some embodiments of the present disclosure.

FIG. 4A illustrates an example computing system that includes a memory sub-system in accordance with some embodiments of the present disclosure.

FIG. 4B is a block diagram of a memory device in communication with a memory sub-system controller of a memory sub-system, according to an embodiment.

### DETAILED DESCRIPTION

Aspects of the present disclosure are directed to an electronic circuit with a selector gate having a nitride-based dielectric barrier and methods of manufacturing thereof.

Storage devices such as solid-state drives (SSDs) may incorporate 3-dimensional (3D) NAND flash memory technology. Traditional NAND flash memory stores data in a 2-dimensional (2D) structure, where memory cells are laid out on a single layer. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers. In order to achieve higher storage capacities and/or improve performance of the device, the number of tiers within a single memory device may be increased, thus allowing for higher-capacity storage devices. However, the increase in the number of tiers also increases the overall height of the 3D NAND structure. “Height” herein refers to the size of the 3D NAND structure that is measured in the direction that is orthogonal to the layers substantially forming the structure. To limit the height of the 3D NAND structure, the thickness of each tier can be decreased.

A 3D NAND device includes metal contacts for accessing the complementary metal-oxide-semiconductor (CMOS) circuits (e.g., transistors) used for managing and/or controlling the memory arrays. The CMOS may be disposed adjacent to (e.g., beneath, etc.) a memory array, reducing the overall device size. The CMOS may control operation of memory cells in the 3D NAND device. The CMOS may select cells that are to be accessed, such as for read and/or write operations. The CMOS may regulate the power, timing and signals sent to individual memory cells, ensuring data can be stored and retrieved efficiently.

The CMOS circuits may use a metal-oxide-semiconductor field-effect transistor (MOSFET) to control access to cells in the memory array. In some embodiments, a double superjunction gate-drain (dSGD) MOSFET is used to control access to memory cells in the memory array. Selector gates in the CMOS circuit(s) may control which memory cells are to be accessed. The selector gates receive either a high signal or a low signal to select a group of memory cell(s) for access. However, the threshold between the high signal and the low signal may become blurred. To overcome the blurring of the high and low signal thresholds, the silicon making up at least part of the selector gates may be doped with boron, in some embodiments. Doping the silicon with boron increases the resistivity of the selector gate, thus increasing the threshold between the high signal and the low signal for the selector gate. However, boron can migrate from the silicon to an adjacent metal oxide during manufacturing process(es), leading to degradation of the metal oxide. For example, during an oxidation process performed with respect to a metal oxide and/or the gate dielectric, boron can migrate from the boron-doped silicon to the metal oxide. The metal oxide may be a super insulator. However, as boron migrates into the metal oxide, the metal oxide becomes at least slightly conductive. Therefore, the metal oxide fails to electrically insulate the selector gate, leading to poor and/or non-uniform performance.

Aspects of the present disclosure may address the deficiencies described above and other challenges by providing an electronic circuit (e.g., a memory array) with a selector gate having a nitride-based dielectric barrier. The electronic circuit described herein may provide more consistent selector gate operation across a device without the adverse affects of boron migration into gate metal oxides. Moreover, the selector gate high and low signal threshold margin may be improved, thus improving the time for programming memory cells and/or improving the read-write bandwidth (RWB) of the memory cells.

In some embodiments, a memory array includes a stack of layers. The stack of layers may be a tier stack. In some embodiments, the tier stack is formed by alternating layers of a first dielectric material and a second dielectric material (e.g., such as alternating layers of silicon oxide and silicon nitride, etc.). A selector gate may be formed within the tier stack, such as at one of the layers of the second dielectric material. In some embodiments, multiple selector gates are formed, each at one of the layers of the second dielectric material. To prevent the migration of boron from a boron-doped poly-silicon layer (e.g., a polycrystalline silicon layer, etc.) of the selector gate, the selector gate may be formed with a nitride-based dielectric barrier adjacent to the boron-doped poly-silicon layer. The nitride-based dielectric barrier may be more dense than the boron-doped poly-silicon layer. Materials having a greater density may resist boron migration (e.g., diffusion, etc.) more than materials having a lesser density. Because of the greater density of the nitride-based dielectric barrier, boron may resist migration from the boron-doped poly-silicon layer to a metal oxide within the tier stack. The metal oxide may be adjacent to and/or form at least a part of the selector gate. During a subsequent oxidation process performed with respect to the metal oxide (e.g., to re-oxidize the metal oxide, etc.), boron may be substantially prevented from migrating from the boron-doped poly-silicon to the metal oxide. In some embodiments, the nitride-based dielectric barrier effectively prevents the boron migration.

Advantages of the present disclosure include, for example, improved performance of a 3D NAND device, such as improved time for programming memory cells and/or improved RWB. These improvements may be realized because of improvements in selector gate performance such as by reducing voltage leakage in the gate and/or by improving the uniformity of the high and low signal threshold margin. Accordingly, the performance of a memory sub-system incorporating an electronic device as described herein can be increased, leading to faster memory operations and/or decreased latency.

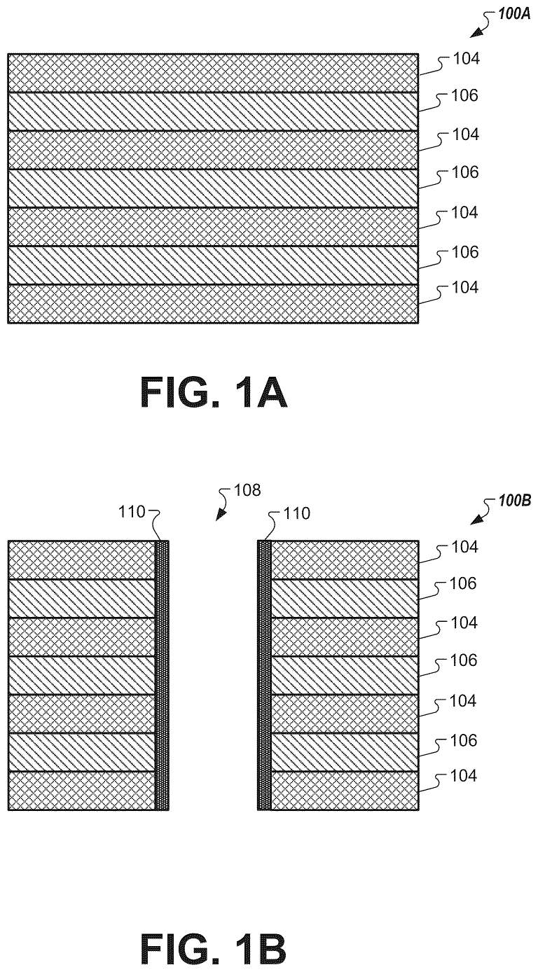

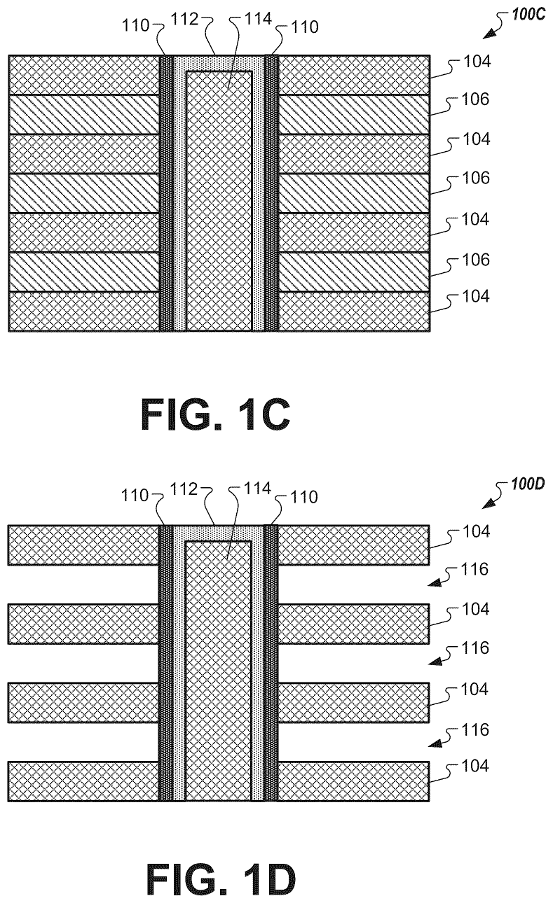

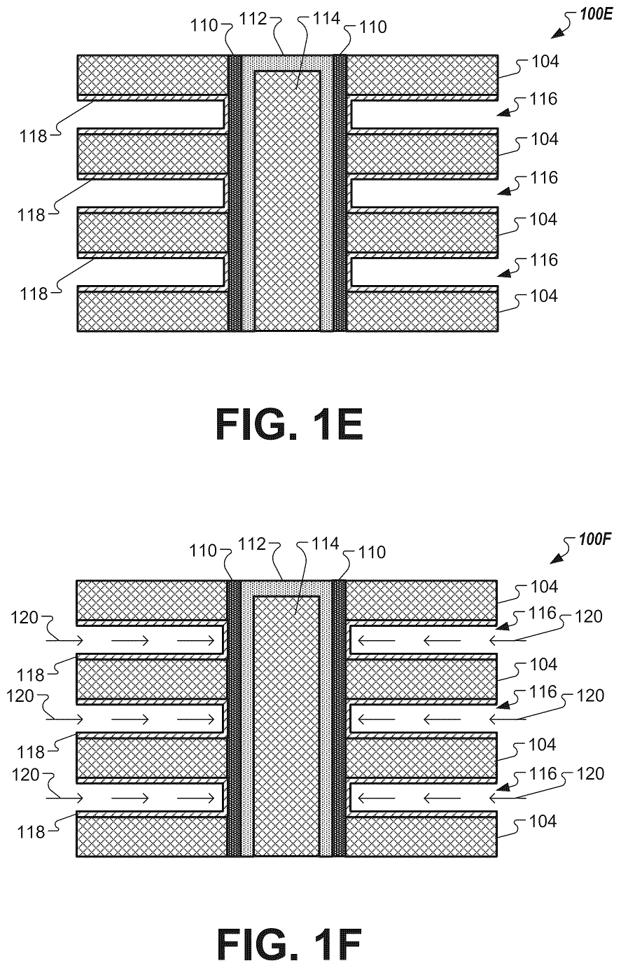

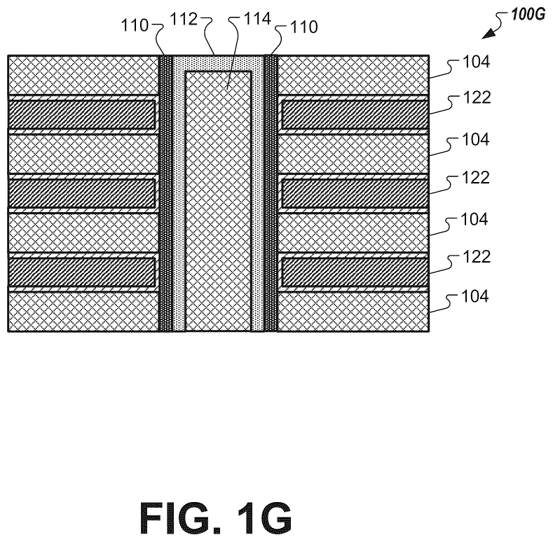

FIGS. 1A-G are cutaway schematic representations illustrating a method of manufacturing an electronic circuit (e.g., a memory array) with a selector gate having a nitride-based dielectric barrier, in accordance with some embodiments of the present disclosure. In some embodiments, each of FIGS. 1A-G illustrate a manufacturing operation for manufacturing at least a portion of a memory array as described herein.

Referring to FIG. 1A, a representation of an operation 100A is shown. In some embodiments, one or more layers are formed. The layers may include oxide layers 104 (e.g., metalloid oxide layers such as silicon oxide layers) and nitride layers 106 (e.g., metalloid nitride layers such as silicon nitride layers). The oxide layers 104 and the nitride layers 106 may alternate within a stack of layers. For example, a first oxide layer 104 may be disposed on top of a first nitride layer 106, a second nitride layer 106 may be disposed on top of the first oxide layer 104, and a second oxide layer 104 may be disposed on top of the second nitride layer 106, and so on. The layers 104 and 106 may form at least part of a CMOS associated with a memory array.

The layers 102-106 may be formed by multiple deposition processes. For example, a first deposition process may be performed to deposit a first oxide layer 104, a second deposition process may be performed to deposit a first nitride layer 106, a third deposition process may be performed to deposit a second oxide layer 104, and so on.

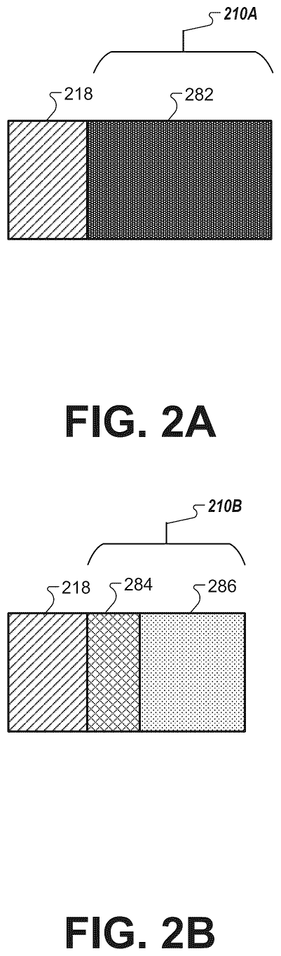

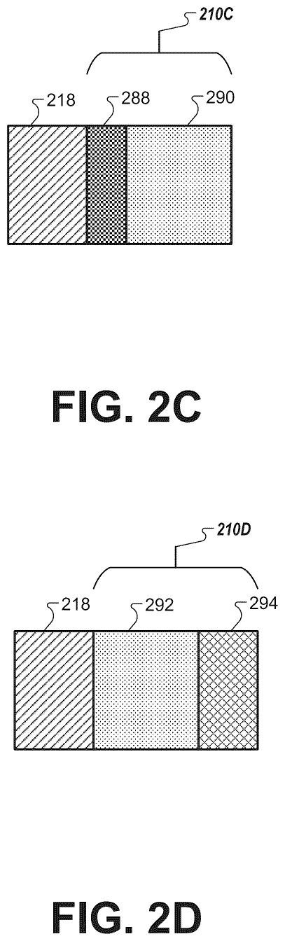

Referring to FIG. 1B, a representation of an operation 100B may be shown. In some embodiments, a hole 108 may be formed in the stack of layers. The hole 108 may be formed by mechanical material removal (e.g., drilling, etc.) and/or by etching (e.g., photo-etching, etc.). In some embodiments, the hole 108 is lined with a gate dielectric barrier 110. The gate dielectric barrier 110 may be a nitride-based dielectric barrier as described herein. The gate dielectric barrier 110 may have one layer or multiple layers. In some embodiments, the gate dielectric barrier 110 includes silicon nitride (SiN) or silicon oxy-nitride (SiOₓN_{y}). The gate dielectric barrier 110 may further include silicon oxide (SiOₓ) and/or a high-K dielectric material such as hafnium nitride (HfN), zirconium nitride (ZrN), or aluminum nitride (AlN), etc. The gate dielectric barrier 110 may include a first layer of one of the above constituents and a second layer of another one of the above constituents. Further details regarding the gate dielectric barrier 110 are described herein below with respect to FIGS. 2A-D.

Referring to FIG. 1C, a representation of an operation 100C may be shown. In some embodiments, a poly-silicon layer 112 (e.g., a polycrystalline silicon layer) is deposited on the surface of gate dielectric barrier 110. An oxide plug 114 (e.g., a metalloid oxide, such as silicon oxide) may be deposited between the poly-silicon layer 112. A poly-silicon cap may be deposited on top of the oxide plug 114 to seal the top of the hole and/or to isolate the oxide plug 114. In some embodiments, the poly-silicon layer 112 is doped with a metalloid, such as boron.

Referring to FIG. 1D, a representation of an operation 100D may be shown. In some embodiments, the nitride layers 106 are exhumed (e.g., removed) from the stack of layers, leaving voids 116 between the layers 104. A selective etch process may be performed to remove the nitride layers 106. For example, an etch process that etches silicon nitride selective to silicon oxide may be performed to remove the nitride layers 106. The selective etch process may include introducing etchants to the nitride layers 106. Etchants may include wet etchants such as hot phosphoric acid or hydrofluoric acid, or dry etchants such as etchant gas or plasma, etc. In some embodiments, voids 116 separate the oxide layers 104.

Referring to FIG. 1E, a representation of an operation 100E may be shown. In some embodiments, a metal oxide layer 118 is deposited on the surfaces forming the voids 116. The metal oxide layer 118 may be deposited on a bottom surface of an oxide layer 104, on a top surface of an oxide layer 104, and on the surface of the gate dielectric barrier 110. In some embodiments, the metal oxide layer 118 includes aluminum oxide. However, the metal oxide layer 118 may include another suitable metal oxide in some embodiments. In some embodiments, the metal oxide layer 118 is to at least partially form a gate dielectric of a selector gate.

Referring to FIG. 1F, a representation of an operation 100F may be shown. In some embodiments, an oxidation process is performed with respect to the metal oxide layers 118. The oxidation process may re-oxidize the metal oxide layers 118, the gate dielectric barrier 110, and/or the poly-silicon layer 112. In some embodiments, the oxidation process at least partially oxidizes at least a portion of the gate dielectric barrier 110. During the oxidation process, a metalloid (e.g., boron) in the poly-silicon layer 112 may tend to migrate (e.g., diffuse) from the poly-silicon layer 112 (that is doped with boron). For example, boron, which is sensitive to oxidation, may tend to migrate from the boron-doped poly-silicon layer 112 towards the metal oxide layers 118 during the oxidation process. However, the gate dielectric layer 110 may substantially prevent the migration of boron to the metal oxide layers 118 on the opposite side of the gate dielectric layer 110 from the boron-doped poly-silicon layer 112. Because boron resists migration through dense materials and because of the density of the gate dielectric layer 110 (e.g., the density of the gate dielectric layer 110 is greater than the density of the poly-silicon layer 112), the boron may not migrate through the gate dielectric layer 110.

In some embodiments, to perform the oxidation process, an oxidizing agent 120 is introduced into the voids 116. The oxidizing agent may be an oxygen-based agent such as dry oxygen (O₂) or Ozone (O₃). The oxidizing agent may be a wet oxidizing agent, such as steam (e.g., at least partially vaporized H₂O) or hydrogen peroxide (H₂O₂). The oxidizing agent may be a nitrogen-based agent such as nitrous oxide (N₂O) or nitric oxide (NO). The oxidizing agent may be plasma-based, such as oxygen plasma, etc. Other oxidizing agents may be used in some embodiments. In some embodiments, the oxidation process is performed at an elevated temperature within a temperature window and/or at an elevated pressure within a pressure window. The temperature window and/or the pressure window may define a range of temperatures and/or pressures at which the oxidation process can occur.

Referring to FIG. 1G, a representation of an operation 100G may be shown. In some embodiments, the voids 116 are filled with metal to form conductive lines 122. The metal may be a conductive metal such as a molybdenum alloy or a tungsten alloy. The metal may be deposited by physical vapor deposition, chemical vapor deposition, atomic layer deposition, or another deposition technique. In some embodiments, molten metal is introduced into the voids 116. The cooled metal may solidify in the voids 116 to form the conductive lines 122. In some embodiments, a gaseous precursor containing the metal may be introduced into the voids. The metal in the gaseous precursor may grow on the metal oxide layers 118 to form the conductive lines 122.

FIGS. 2A-D are cutaway schematic representations of portions of nitride-based dielectric barriers 210A-D, in accordance with some embodiments of the present disclosure. Each of the nitride-based dielectric barriers 210A-D may correspond to gate dielectric barrier 110 described herein above. In some embodiments, the nitride-based dielectric barriers 210A-D include a nitride (e.g., a silicon nitride, an aluminum nitride, etc.) as a constituent. In some embodiments, each of the nitride-based dielectric barriers 210A-D substantially prevent boron diffusion from a boron-doped metalloid layer (e.g., a boron-doped poly-silicon layer) on one side of the barrier to a metal oxide layer (e.g., an aluminum oxide layer) on an opposite side of the barrier. Each of the nitride-based dielectric barriers 210A-D may have one layer of dielectric material or may have two or more layers of dielectric material. Each of the nitride-based dielectric barriers 210A-D may have a total thickness. The total thickness may include all the layers of the barrier. In some embodiments, the nitride-based dielectric barriers 210A-D have a thickness between approximately 0.5 nanometers and approximately 20 nanometers. In some embodiments, the nitride-based dielectric barriers 210A-D have a thickness between approximately 1 nanometer and approximately 15 nanometers. In some embodiments, the nitride-based dielectric barriers 210A-D have a thickness of approximately 10 nanometers.

Referring to FIG. 2A, a nitride-based dielectric barrier 210A is shown. The nitride-based dielectric barrier 210A is shown adjacent to a metal oxide layer 218. The metal oxide layer 218 may correspond to metal oxide layers 118 described herein above. In some embodiments, the metal oxide layer 218 is an aluminum oxide layer. In some embodiments, the nitride-based dielectric barrier 210A includes a silicon oxy-nitride layer 282 (e.g., a layer of SiOₓN_{y}). In some embodiments, the silicon oxy-nitride layer 282 has a density between approximately 2.7 g/cm³ and approximately 3.1 g/cm³. The density of the silicon oxy-nitride layer 282 may vary based on the relative constituents of oxygen and nitrogen. In some embodiments, the density of the nitride-based dielectric barrier 210A is greater than the density of the metal oxide layer 218.

Referring to FIG. 2B, a nitride-based dielectric barrier 210B is shown. In some embodiments, the nitride-based dielectric layer 210B includes a first layer 284 and a second layer 286. In some embodiments, the first layer 284 is a silicon nitride (SiN) layer and the second layer 286 is a silicon oxide (SiOₓ) or a silicon oxy-nitride (SiOₓN_{y}) layer. Alternatively, in some embodiments, the first layer 284 is a silicon oxy-nitride (SiOₓN_{y}) layer and the second layer 284 is a silicon oxide (SiOₓ) layer. The first layer 284 may have a thickness less than the thickness of the second layer 286. However, the total thickness of the nitride-based dielectric barrier 210B may be between approximately 0.5 nanometers and approximately 20 nanometers, between approximately 1 nanometer and approximately 15 nanometers, or may be approximately 10 nanometers as described herein above. In some embodiments, the combined density of the nitride-based dielectric barrier 210B is greater than the density of the metal oxide layer 218.

Referring to FIG. 2C, a nitride-based dielectric barrier 210C is shown. In some embodiments, the nitride-based dielectric barrier 210C includes a first layer 288 and a second layer 290. In some embodiments, the first layer 288 is a high-K dielectric layer and the second layer 290 is a silicon oxy-nitride (SiOₓN_{y}) layer. In some embodiments, the first layer 288 may be a layer of a high-K dielectric material selected from a group including hafnium nitride, zirconium nitride, and aluminum nitride. The first layer 288 may have a dielectric constant greater than a threshold value. For example, and in some embodiments, the first layer 288 may have a dielectric constant greater than approximately 8. In some embodiments, the first layer 288 may have a dielectric constant greater than approximately 10. The first layer 288 may have a thickness less than the thickness of the second layer 290. However, the total thickness of the nitride-based dielectric barrier 210C may be between approximately 0.5 nanometers and approximately 20 nanometers, between approximately 1 nanometer and approximately 15 nanometers, or may be approximately 10 nanometers as described herein above. In some embodiments, the combined density of the nitride-based dielectric barrier 210C is greater than the density of the metal oxide layer 218. In some embodiments, the density of the first layer 288 is greater than the density of the metal oxide layer 218.

Referring to FIG. 2D, a nitride-based dielectric barrier 210D is shown. In some embodiments, the nitride-based dielectric barrier 210D includes a first layer 292 and a second layer 294. In some embodiments, the first layer 292 is a layer of silicon oxide (SiOₓ) or a layer of silicon oxy-nitride (SiOₓN_{y}). In some embodiments, the second layer 294 is a layer of silicon nitride (SiN), hafnium nitride (HfN), zirconium nitride (ZrN), or aluminum nitride (AlN). In some embodiments, the second layer 294 is a high-K dielectric layer. The thickness of the second layer 294 may be thinner than the thickness of the first layer 292. However, the total thickness of the nitride-based dielectric barrier 210D may be between approximately 0.5 nanometers and approximately 20 nanometers, between approximately 1 nanometer and approximately 15 nanometers, or may be approximately 10 nanometers as described herein above. In some embodiments, the combined density of the nitride-based dielectric barrier 210D is greater than the density of the metal oxide layer 218.

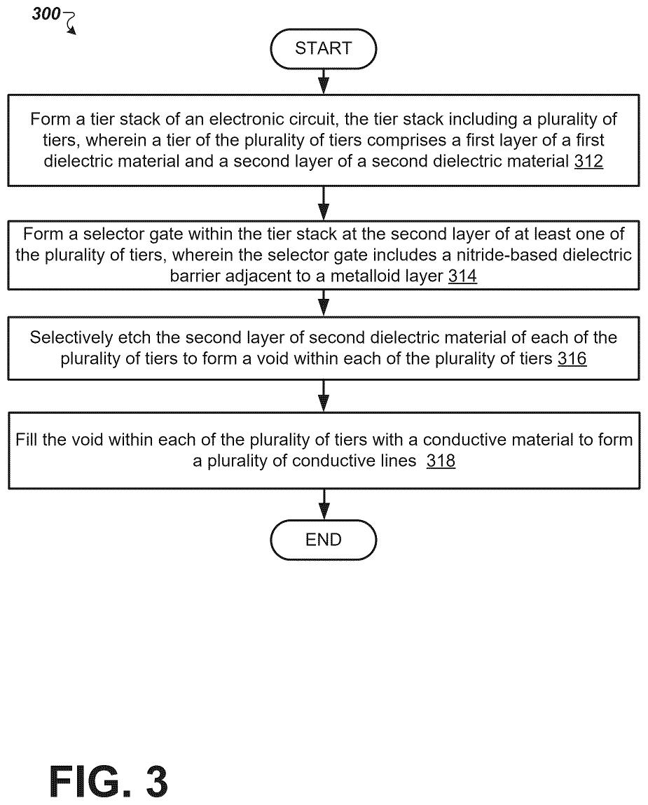

FIG. 3 is a flow diagram of an example method 300 of manufacturing an electronic circuit having a nitride-based dielectric barrier, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 312, a tier stack of an electronic circuit is formed. The electronic circuit may be a memory array. The tier stack may include a plurality of tiers. In some embodiments, a tier includes a first layer of a first dielectric material and a second layer of a second dielectric material. The first dielectric material may be a metalloid oxide such as silicon oxide and the second dielectric material may be a metalloid nitride such as silicon nitride. The tier stack may include alternating oxide and nitride layers. For example, alternating layers of silicon oxide and silicon nitride may be stacked on top of one another to form the tier stack. The layers may be formed by multiple deposition processes. For example, a first deposition process may be performed to deposit a first oxide layer, a second deposition process may be performed to deposit a first nitride layer on the first oxide layer, a third deposition process may be performed to deposit a second oxide layer on the first nitride layer, etc.

At block 314, a selector gate may be formed within the tier stack at the second layer of at least one of the plurality of tiers. In some embodiments, the selector gate includes a nitride-based dielectric barrier adjacent to a metalloid layer. The selector gate may be formed by forming a hole through at least a portion of the tier stack and depositing one or more layers on the walls of the hole. In some embodiments, a nitride-based dielectric barrier (e.g., gate dielectric barrier 110) is deposited on the wall surfaces of the hole. A metalloid layer (e.g., poly-silicon layer 112) may be deposited on the surface of the nitride-based dielectric barrier.

At block 316, the second layer of second dielectric material of each of the plurality of tiers is selectively etched (e.g., selective to the first dielectric material) to form a void within each of the plurality of tiers. In some embodiments, a selective etch process is performed to etch the second dielectric material selective to the first dielectric material. The selective etch process may include introducing an etchant to the second dielectric material. In some embodiments, a metal oxide layer is deposited on surfaces forming each of the formed voids. The metal oxide layer may be an aluminum oxide layer. In some embodiments, oxidation of the metal oxide layer is performed. The metalloid layer deposited at block 314 may be doped with another metalloid. For example, a poly-silicon layer (e.g., the metalloid layer) may be doped with boron (e.g., another metalloid), forming a boron-doped poly-silicon layer. In some embodiments, during the performance of the oxidation, the nitride-based dielectric barrier prevents migration of the another metalloid (e.g., boron) from the metalloid layer (e.g., the poly-silicon layer) as described herein.

At block 318, the void within each of the plurality of tiers is filled with a conductive material to form a plurality of conductive lines. In some embodiments, the voids are filled with a conductive metal such as a molybdenum alloy or a tungsten alloy. Other conductive metals are possible. The metal may be deposited by PVD, CVD, ALD, or another process as described herein.

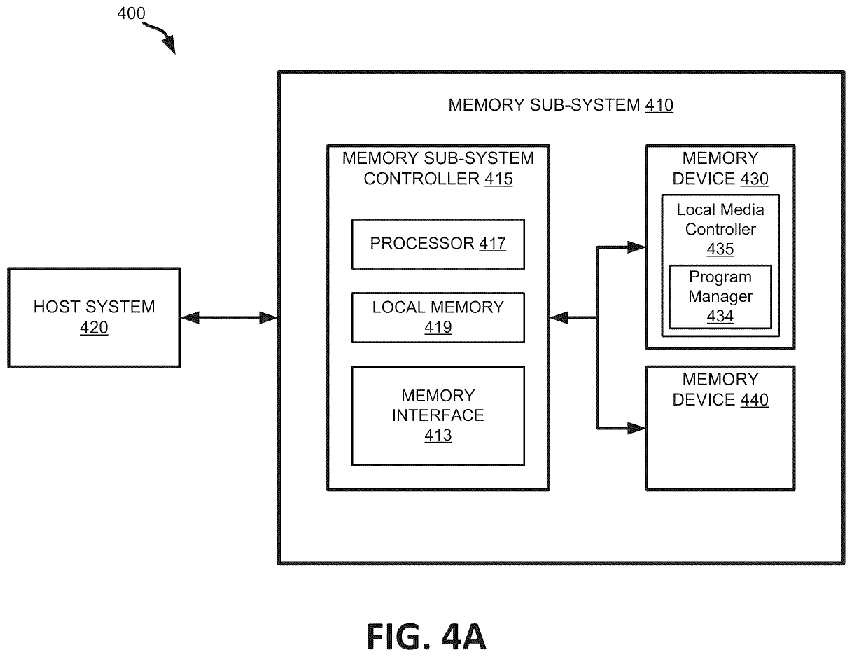

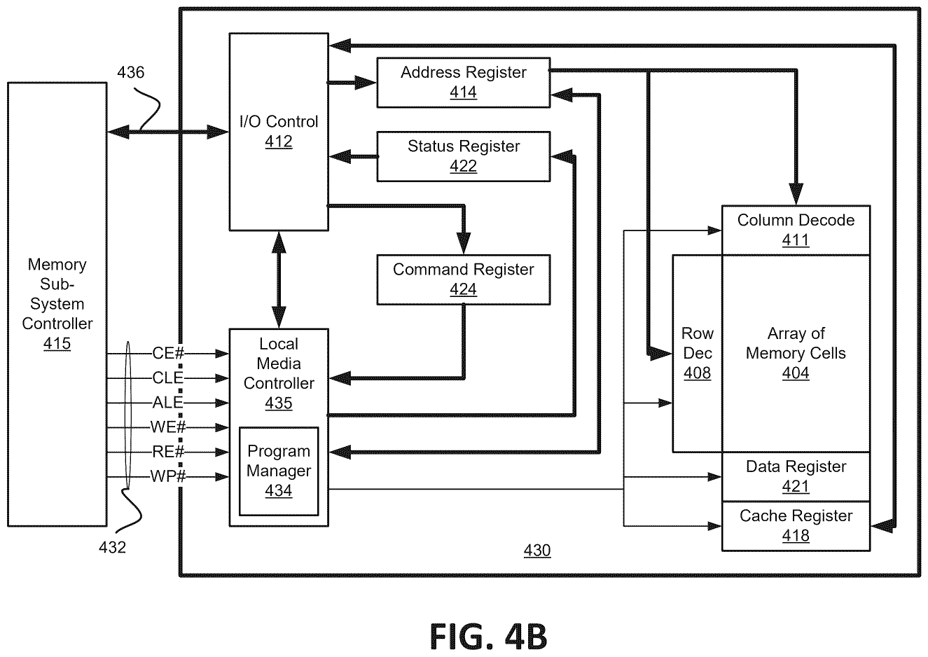

FIG. 4A illustrates an example computing system 400 that includes a memory sub-system 410 in accordance with some embodiments of the present disclosure. In some embodiments, one or more components of computing system 400 include an electronic circuit with a selector gate having a nitride-based dielectric barrier as described herein above. The memory sub-system 410 can include media, such as one or more volatile memory devices (e.g., memory device 440), one or more non-volatile memory devices (e.g., memory device 430), or a combination of such.

A memory sub-system 410 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 400 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 400 can include a host system 420 that is coupled to one or more memory sub-systems 410. In some embodiments, the host system 420 is coupled to multiple memory sub-systems 410 of different types. FIG. 4A illustrates one example of a host system 420 coupled to one memory sub-system 410. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 420 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 420 uses the memory sub-system 410, for example, to write data to the memory sub-system 410 and read data from the memory sub-system 410.

The host system 420 can be coupled to the memory sub-system 410 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 420 and the memory sub-system 410. The host system 420 can further utilize an NVM Express (NVMe) interface to access components (e.g., memory devices 430) when the memory sub-system 410 is coupled with the host system 420 by the physical host interface (e.g., PCIe bus). The physical host interface can provide an interface for passing control, address, data, and other signals between the memory sub-system 410 and the host system 420. FIG. 4A illustrates a memory sub-system 410 as an example. In general, the host system 420 can access multiple memory sub-systems via a same communication connection, multiple separate communication connections, and/or a combination of communication connections.

The memory devices 430, 440 can include any combination of the different types of non-volatile memory devices and/or volatile memory devices. The volatile memory devices (e.g., memory device 440) can be random access memory (RAM), such as dynamic random access memory (DRAM) and synchronous dynamic random access memory (SDRAM).

Some examples of non-volatile memory devices (e.g., memory device 430) include a negative- and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 430 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 430 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 430 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 430 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative- or (NOR) flash memory, or electrically erasable programmable read-only memory (EEPROM).

A memory sub-system controller 415 (or controller 415 for simplicity) can communicate with the memory devices 430 to perform operations such as reading data, writing data, or erasing data at the memory devices 430 and other such operations. The memory sub-system controller 415 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 415 can be a microcontroller, special purpose logic circuitry (e.g., a field programmable gate array (FPGA), an application specific integrated circuit (ASIC), etc.), or other suitable processor.

The memory sub-system controller 415 can include a processing device, which includes one or more processors (e.g., processor 417), configured to execute instructions stored in a local memory 419. In the illustrated example, the local memory 419 of the memory sub-system controller 415 includes an embedded memory configured to store instructions for performing various processes, operations, logic flows, and routines that control operation of the memory sub-system 410, including handling communications between the memory sub-system 410 and the host system 420.

In some embodiments, the local memory 419 can include memory registers storing memory pointers, fetched data, etc. The local memory 419 can also include read-only memory (ROM) for storing micro-code. While the example memory sub-system 410 in FIG. 4A has been illustrated as including the memory sub-system controller 415, in another embodiment of the present disclosure, a memory sub-system 410 does not include a memory sub-system controller 415, and can instead rely upon external control (e.g., provided by an external host, or by a processor or controller separate from the memory sub-system).

In general, the memory sub-system controller 415 can receive commands or operations from the host system 420 and can convert the commands or operations into instructions or appropriate commands to achieve the desired access to the memory devices 430. The memory sub-system controller 415 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 430. The memory sub-system controller 415 can further include host interface circuitry to communicate with the host system 420 via the physical host interface. The host interface circuitry can convert the commands received from the host system into command instructions to access the memory devices 430 as well as convert responses associated with the memory devices 430 into information for the host system 420.

The memory sub-system 410 can also include additional circuitry or components that are not illustrated. In some embodiments, the memory sub-system 410 can include a cache or buffer (e.g., DRAM) and address circuitry (e.g., a row decoder and a column decoder) that can receive an address from the memory sub-system controller 415 and decode the address to access the memory devices 430.

In some embodiments, the memory devices 430 include local media controllers 435 that operate in conjunction with memory sub-system controller 415 to execute operations on one or more memory cells of the memory devices 430. An external controller (e.g., memory sub-system controller 415) can externally manage the memory device 430 (e.g., perform media management operations on the memory device 430). In some embodiments, memory sub-system 410 is a managed memory device, which is a raw memory device 430 having control logic (e.g., local media controller 435) on the die and a controller (e.g., memory sub-system controller 415) for media management within the same memory device package. An example of a managed memory device is a managed NAND (MNAND) device.

The memory sub-system 410 includes a memory interface component 413 that can handle interactions of memory sub-system controller 415 with the memory devices of memory sub-system 410, such as memory device 430. For example, memory interface component 413 can receive data from memory device 430, such as data retrieved in response to a read operation or a write operation. In some examples, the memory sub-system controller 415 can include a processor 417 (processing device) configured to execute instructions stored in local memory 419 for performing the operations described herein.

In some embodiments, memory device 430 includes a program manager 434. In some embodiments, local media controller 435 includes at least a portion of program manager 434 and is configured to perform various memory functions. In some embodiments, the program manager 434 is part of the host system 410, an application, or an operating system. Further details with regards to the operations of program manager 434 are described below. In some embodiments, program manager 434 is implemented on memory device 430 using firmware, hardware components, or a combination of the above.

FIG. 4B is a simplified block diagram of a first apparatus, in the form of a memory device 430, in communication with a second apparatus, in the form of a memory sub-system controller 415 of a memory sub-system (e.g., memory sub-system 410 of FIG. 4A), according to an embodiment. In some embodiments, one or more components of memory device 430 may be manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 415 (e.g., a controller external to the memory device 430), can be a memory controller or other external host device.

Memory device 430 includes an array of memory cells 404 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 4B) of at least a portion of array of memory cells 404 are capable of being programmed to one of at least two target data states.

Row decode circuitry 408 and column decode circuitry 411 are provided to decode address signals. Address signals are received and decoded to access the array of memory cells 404. Memory device 430 also includes input/output (I/O) control circuitry 412 to manage input of commands, addresses and data to the memory device 430 as well as output of data and status information from the memory device 430. An address register 414 is in communication with I/O control circuitry 412 and row decode circuitry 408 and column decode circuitry 411 to latch the address signals prior to decoding. A command register 424 is in communication with I/O control circuitry 412 and local media controller 435 to latch incoming commands.

A controller (e.g., the local media controller 435 internal to the memory device 430) controls access to the array of memory cells 404 in response to the commands and generates status information for the external memory sub-system controller 415, i.e., the local media controller 435 is configured to perform access operations (e.g., read operations, programming operations and/or erase operations) on the array of memory cells 404. The local media controller 435 is in communication with row decode circuitry 408 and column decode circuitry 411 to control the row decode circuitry 408 and column decode circuitry 411 in response to the addresses. In at least one embodiment, local media controller 435 includes program manager 434, which can implement the bad block mapping operations with respect to memory device 430, as described herein.

The local media controller 435 is also in communication with a cache register 418. Cache register 418 latches data, either incoming or outgoing, as directed by the local media controller 435 to temporarily store data while the array of memory cells 404 is busy writing or reading, respectively, other data. During a programming operation (e.g., a write operation), data can be passed from the cache register 418 to the data register 421 for transfer to the array of memory cells 404; then new data can be latched in the cache register 418 from the I/O control circuitry 412. During a read operation, data can be passed from the cache register 418 to the I/O control circuitry 412 for output to the memory sub-system controller 415; then new data can be passed from the data register 421 to the cache register 418. The cache register 418 and/or the data register 421 can form (e.g., can form a portion of) a page buffer of the memory device 430. A page buffer can further include sensing devices (not shown in FIG. 4B) to sense a data state of a memory cell of the array of memory cells 404, e.g., by sensing a state of a data line connected to that memory cell. A status register 422 can be in communication with I/O control circuitry 412 and the local memory controller 435 to latch the status information for output to the memory sub-system controller 415.

Memory device 430 receives control signals at the memory sub-system controller 415 from the local media controller 435 over a control link 432. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 432 depending upon the nature of the memory device 430. In at least one embodiment, memory device 430 receives command signals (which represent commands), address signals (which represent addresses), and data signals (which represent data) from the memory sub-system controller 415 over a multiplexed input/output (I/O) bus 436 and outputs data to the memory sub-system controller 415 over I/O bus 436.

For example, the commands can be received over input/output (I/O) pins [7:0] of I/O bus 436 at I/O control circuitry 412 and can then be written into command register 424. The addresses can be received over input/output (I/O) pins [7:0] of I/O bus 436 at I/O control circuitry 412 and can then be written into address register 414. The data can be received over input/output (I/O) pins [7:0] for an 8-bit device or input/output (I/O) pins [15:0] for a 16-bit device at I/O control circuitry 412 and then can be written into cache register 418. The data can be subsequently written into data register 421 for programming the array of memory cells 404.

In at least one embodiment, cache register 418 can be omitted, and the data can be written directly into data register 421. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 430 by an external device (e.g., the memory sub-system controller 415), such as conductive pads or conductive bumps as are commonly used.

In some implementations, additional circuitry and signals can be provided, and that the memory device 430 of FIG. 4B has been simplified. It should be recognized that the functionality of the various block components described with reference to FIG. 4B cannot necessarily be segregated to distinct components or component portions of an integrated circuit device. For example, a single component or component portion of an integrated circuit device could be adapted to perform the functionality of more than one block component of FIG. 4B. Alternatively, one or more components or component portions of an integrated circuit device could be combined to perform the functionality of a single block component of FIG. 4B. Additionally, while specific I/O pins are described for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming a tier stack of an electronic circuit, the tier stack comprising a plurality of tiers, wherein a tier of the plurality of tiers comprises a first layer of a first dielectric material and a second layer of a second dielectric material;
forming a selector gate within the tier stack at the second layer of at least one of the plurality of tiers, wherein the selector gate comprises a nitride-based dielectric barrier adjacent to a metalloid layer, wherein the metalloid layer comprises a first metalloid;
selectively etching the second layer of second dielectric material of each of the plurality of tiers to form a void within each of the plurality of tiers; and
filling the void within each of the plurality of tiers with a conductive material to form a plurality of conductive lines.

2. The method of claim 1, further comprising:
depositing a metal oxide on surfaces forming the void within each of the plurality of tiers; and
performing oxidation of the metal oxide, wherein the metalloid layer is doped with a second metalloid, and wherein the nitride-based dielectric barrier prevents migration of the second metalloid from the metalloid layer to the metal oxide.

3. The method of claim 2, wherein the first metalloid comprises poly-silicon and the second metalloid comprises boron.

4. The method of claim 1, wherein forming the selector gate comprises:
depositing a first layer of the nitride-based dielectric barrier on a surface formed by the metalloid layer; and
depositing a second layer of the nitride-based dielectric barrier on the first layer.

5. The method of claim 1, wherein the nitride-based dielectric barrier comprises at least one of silicon nitride (SiN) or silicon oxy-nitride (SiOₓN_{y}).

6. The method of claim 5, wherein the nitride-based dielectric barrier further comprises at least one of silicon oxide (SiOₓ) or a high-K dielectric material selected from a group comprising hafnium nitride (HfN), zirconium nitride (ZrN), and aluminum nitride (AlN).

7. The method of claim 1, wherein the first dielectric material comprises a metalloid oxide and wherein the second dielectric material comprises a metalloid nitride.

8. The method of claim 1, wherein the metal comprises a molybdenum alloy or a tungsten alloy.

9. The method of claim 1, wherein the electronic circuit comprises a memory array, and wherein the selector gate is a gate of a metal-oxide-semiconductor field-effect transistor (MOSFET) of the memory array.

10. A memory array, comprising:
a stack of layers;
a selector gate at one or more layers of the stack of layers, wherein the selector gate comprises a nitride-based dielectric barrier adjacent to a metalloid layer, wherein the metalloid layer comprises a first metalloid; and
a plurality of conductive lines formed within the stack of layers.

11. The memory array of claim 10, wherein the metalloid layer is doped with a second metalloid, and wherein the nitride-based dielectric barrier prevents migration of the second metalloid to a metal oxide on an opposite side of the nitride-based dielectric barrier from the metalloid layer.

12. The memory array of claim 11, wherein the first metalloid comprises poly-silicon and the second metalloid comprises boron.

13. The memory array of claim 10, wherein the nitride-based dielectric barrier has a thickness between approximately 0.5 nanometers and approximately 20 nanometers.

14. The memory array of claim 10, wherein the nitride-based dielectric barrier comprises at least one of silicon nitride (SiN) or silicon oxy-nitride (SiOₓN_{y}).

15. The memory array of claim 14, wherein the nitride-based dielectric barrier further comprises at least one of silicon oxide (SiOₓ) or a high-K dielectric material selected from a group comprising hafnium nitride (HfN), zirconium nitride (ZrN), and aluminum nitride (AlN).

16. The memory array of claim 11, wherein the selector gate is a gate of a metal-oxide-semiconductor field-effect transistor (MOSFET) of the memory array.

17. An electronic device, comprising:
a tier stack comprising a plurality of tiers;
a plurality of conductive lines formed within the tier stack; and
a selector gate formed at one or more layers of the tier stack, wherein the selector gate comprises a dielectric barrier adjacent to a metalloid layer, wherein the metalloid layer comprises a first metalloid, and wherein the dielectric barrier comprises at least one of silicon nitride (SiN) or silicon oxy-nitride (SiOₓN_{y}).

18. The electronic device of claim 17, wherein the dielectric barrier further comprises at least one of silicon oxide (SiOₓ) or a high-K dielectric material selected from a group comprising hafnium nitride (HfN), zirconium nitride (ZrN), and aluminum nitride (AlN).

19. The electronic device of claim 17, wherein the metalloid layer is doped with a second metalloid, and wherein the first metalloid comprises poly-silicon and the second metalloid comprises boron.

20. The electronic device of claim 17, wherein the electronic device comprises a memory array, and wherein the selector gate is a gate of a metal-oxide-semiconductor field-effect transistor (MOSFET) of the memory array.
